(19) United States
(12) Patent Application Publication
(10) Pub. No.: US 2016/0025791 A1
(43) Pub. Date: Jan. 28, 2016

(54) OVERCURRENT DETECTING CIRCUIT AND LEAKAGE CURRENT DETECTING CIRCUIT

(71) Applicant: Samsung Display Co., Ltd., Yongin-City (KR)

(72) Inventors: Jong-Man Bae, Seoul (KR); Byung-Hyuk Shin, Seoul (KR)

(21) Appl. No.: 14/579,357

(22) Filed: Dec. 22, 2014

(30) Foreign Application Priority Data
Jul. 28, 2014 (KR) 10-2014-0095523

(51) Int. Cl. G01R 31/02; G01R 19/165; G01R 31/40

(52) U.S. Cl. CPC G01R 31/025; G01R 31/40; G01R 19/16538

(57) ABSTRACT

An overcurrent detecting circuit and a leakage current detecting circuit are disclosed. In one aspect, the overcurrent detecting circuit of a display device supplying a power voltage to a display panel through a plurality of power supply lines. The overcurrent detecting circuit includes a plurality of power voltage measurement lines electrically connected to different points of the power supply lines. The overcurrent detecting circuit also includes a plurality of voltage measurement units respectively electrically connected to the power voltage measurement lines. The voltage measurement units are configured to measure the power voltage at the different points through the power voltage measurement lines and generate a plurality of measurement voltages based at least in part on the measured power voltages. The overcurrent detecting circuit further includes a controller configured to detect presence of an overcurrent based at least in part on the measurement voltages.

### CROSS-REFERENCE TO RELATED APPLICATIONS

This application claims priority under 35 USC §119 to Korean Patent Applications No. 10-2014-0095523, filed on Jul. 28, 2014 in the Korean Intellectual Property Office (KIPO), the contents of which are incorporated herein in its entirety by reference.

### BACKGROUND

1. Field

The described technology generally relates to an overcurrent detecting circuit and a leakage current detecting circuit.

2. Description of the Related Technology

Recently, various flat panel display technologies with low weight and volume have been developed. These technologies include liquid crystal displays (LCDs), field emission displays (FEDs), plasma display panels (PDPs), organic light-emitting diode (OLED) displays, etc.

### SUMMARY OF CERTAIN INVENTIVE ASPECTS

One inventive aspect is an overcurrent detecting circuit for a display device.

Another aspect is a leakage current detecting circuit for a display device.

Another aspect is an overcurrent detecting circuit of a display device that can supply a power voltage to a display panel having a pixels through a power supply line. The overcurrent detecting circuit can include a power voltage measurement lines electrically connected to different points of the power supply line, a voltage measurement units respectively electrically connected to the power voltage measurement lines, the voltage measurement units configured to measure the power voltage at the different points of the power supply line through the power voltage measurement lines and to generate a measurement voltages based on the measured power voltage at the different points, and a control unit configured to determine whether an overcurrent occurs based on the measurement voltages.

In example embodiments, each of the voltage measurement units includes a comparator that compares the power voltage to a predetermined reference voltage.

In example embodiments, the comparator outputs the measurement voltage having a first voltage level when the power voltage is lower than the reference voltage.

In example embodiments, the control unit decides that the overcurrent occurs when at least one of the measurement voltages has the first voltage level.

In example embodiments, the control unit cuts off the power voltage supplied to the display panel when the overcurrent is decided to occur.

Another aspect is an overcurrent detecting circuit of a display device that can supply a power voltage to a display panel having a pixels through a power supply line. The overcurrent detecting circuit can include a input power voltage measurement lines formed to measure the power voltage of the power supply line before a voltage drop of the power voltage occurs, a output power voltage measurement lines formed to measure the power voltage of the power supply line after the voltage drop of the power voltage occurs, a voltage measurement units configured to measure the power voltage of the power supply line before the voltage drop occurs through the input power voltage measurement lines and the power voltage of the power supply line after the voltage drop occurs through the output power voltage measurement lines, and to generate a measurement voltages based on the measured power voltage before and after the voltage drop, and a control unit configured to determine whether an overcurrent occurs based on the measurement voltages.

In example embodiments, each of the voltage measurement units includes a calculator configured to output a calculation voltage that is a difference between the power voltage before the voltage drop occurs and the power voltage after the voltage drop occurs and a comparator configured to compare the calculation voltage output from the calculator to a predetermined reference voltage.

In example embodiments, the comparator outputs the measurement voltage having a first voltage level when the power voltage is lower than the reference voltage.

In example embodiments, the control unit decides that the overcurrent occurs when at least one of the measurement voltages has the first voltage level.

In example embodiments, the control unit cuts off the power voltage supplied to the display panel when the overcurrent is decided to occur.

Another aspect is a leakage current detecting circuit of a display device that can supply a power voltage from a power supply unit to a display panel having a pixels through a power supply line. The leakage current detecting circuit can include a switching unit formed between the power supply unit and the display panel, the switching unit configured to transfer the power voltage to the display panel through the power supply line in response to a first signal provided from an external device, a measurement unit formed between the power supply unit and the display panel, the measurement unit configured to transfer the power voltage to the display panel through the power supply line in response to a second signal provided from the external device and to generate a measurement voltage corresponding to a current that flows through the power supply line, and a control unit configured to determine whether a leakage current occurs based on the measurement voltage.

In example embodiments, the switching unit includes a first switching transistor that is turned on in response to the first signal.

In example embodiments, the first switching transistor is turned off when a black image is displayed on the display panel.

In example embodiments, the measurement unit includes a second switching transistor turned on in response to the second signal and a current sensing unit electrically connected to the second transistor, the current sensing unit configured to generate the measurement voltage corresponding to the current that flows through the power supply line.

In example embodiments, the second switching transistor is turned on when a black image is displayed on the display panel.

In example embodiments, the control unit decides that the leakage current occurs when the measurement voltage output from the measurement unit is higher than a predetermined reference voltage.

In example embodiments, the control unit cuts off the power voltage supplied to the display panel when the leakage current is decided to occur.

Another aspect is an overcurrent detecting circuit of a display device supplying a power voltage to a display panel through a plurality of power supply lines. The overcurrent detecting circuit comprises a plurality of power voltage measurement lines electrically connected to different points of the power supply lines. The overcurrent detecting circuit also comprises a plurality of voltage measurement units respectively electrically connected to the power voltage measurement lines and configured to i) measure the power voltage at the different points through the power voltage measurement lines and ii) generate a plurality of measurement voltages based at least in part on the measured power voltages. The overcurrent detecting circuit further comprises a controller configured to detect presence of an overcurrent based at least in part on the measurement voltages.

In the above overcurrent detecting circuit, each of the voltage measurement units includes a comparator configured to compare the power voltage to a predetermined reference voltage.

In the above overcurrent detecting circuit, the comparator is further configured to output the measurement voltages having a first voltage level when the power voltage is lower than the predetermined reference voltage.

In the above overcurrent detecting circuit, the controller is further configured to detect the presence of the overcurrent when at least one of the measurement voltages has the first voltage level.

In the above overcurrent detecting circuit, the controller is further configured to cut off the power voltage supplied to the display panel when the presence of the overcurrent is detected.

In the above overcurrent detecting circuit, the controller comprises an AND gate having the measurement voltages as the input and a control signal as the output, and wherein the control signal indicates the presence of the overcurrent.

Another aspect is an overcurrent detecting circuit of a display device supplying a power voltage to a display panel through a plurality of power supply lines, the overcurrent detecting circuit comprising a plurality of input power voltage measurement lines formed to measure the power voltage before a voltage drop of the power voltage occurs. The overcurrent detecting circuit also comprises a plurality of output power voltage measurement lines formed to measure the power voltage after the voltage drop of the power voltage occurs. The overcurrent detecting circuit further comprises a plurality of voltage measurement units configured to i) measure the power voltages before and after the voltage drop occurs respectively through the input and output power voltage measurement lines and ii) generate a plurality of measurement voltages based at least in part on the measured power voltages. The overcurrent detecting circuit also comprises a controller configured to detect presence of an overcurrent based at least in part on the measurement voltages.

In the above overcurrent detecting circuit, each voltage measurement unit includes a calculator configured to output a calculation voltage that is the difference between the power voltages and a comparator configured to compare the calculation voltage to a predetermined reference voltage.

In the above overcurrent detecting circuit, the comparator is further configured to output the measurement voltage having a first voltage level when the power voltage is lower than the predetermined reference voltage.

In the above overcurrent detecting circuit, the controller is further configured to detect the presence of the overcurrent when at least one of the measurement voltages has the first voltage level.

In the above overcurrent detecting circuit, the controller is further configured to cut off the power voltage supplied to the display panel when the presence of the overcurrent is detected.

In the above overcurrent detecting circuit, the controller comprises an AND gate having the measurement voltages as the input and a control signal as the output, and wherein the control signal indicates the presence of the overcurrent.

Another aspect is a leakage current detecting circuit of a display device supplying a power voltage from a power supply unit to a display panel through a plurality of power supply lines, the leakage current detecting circuit comprising a switching unit formed between the power supply unit and the display panel and configured to provide the power voltage to the display panel based at least in part on a first signal provided from an external device. The leakage current detecting circuit also comprises a measurement unit formed between the power supply unit and the display panel and configured to i) transmit the power voltage to the display panel based at least in part on a second signal provided from the external device and ii) generate a measurement voltage corresponding to a current configured to flow through the power supply lines. The leakage current detecting circuit further comprises a controller configured to detect presence of a leakage current based at least in part on the measurement voltage.

In the above leakage current detecting circuit, the switching unit includes a first switching transistor configured to be turned on based at least in part on the first signal.

In the above leakage current detecting circuit, the first switching transistor is configured to be turned off when a black image is displayed on the display panel.

In the above leakage current detecting circuit, the measurement unit includes a second switching transistor configured to be turned on based at least in part on the second signal. In the above leakage current detecting circuit, the measurement unit also includes a current sensor electrically connected to the second transistor and configured to generate the measurement voltage corresponding to the current configured to flow through the power supply lines.

In the above leakage current detecting circuit, the second switching transistor is configured to be turned on when a black image is displayed on the display panel.

In the above leakage current detecting circuit, the controller is further configured to determine the presence of the leakage current when the measurement voltage is higher than a predetermined reference voltage.

In the above leakage current detecting circuit, the controller is further configured to cut off the power voltage supplied to the display panel when the presence of the leakage current is detected.

In the above leakage current detecting circuit, the controller is further configured to transmit a control signal indicating the presence of the leakage current to the power supply unit.

According to at least one of the disclosed embodiments, an overcurrent detecting circuit can couple a power supply line to a power voltage measurement line and can accurately determine whether an overcurrent occurs based on a power voltage measured at the power voltage measurement line.

A leakage current detecting circuit according to example embodiments can measure a current flowing through a power supply line and can accurately determine whether a leakage current occurs based on the current.

Further, the overcurrent detecting circuit and the leakage current detecting circuit according to example embodiments can prevent a damage of a display device by accurately determining whether the overcurrent and the leakage current occur.

### BRIEF DESCRIPTION OF THE DRAWINGS

FIG. 1 is a block diagram illustrating an overcurrent detecting circuit according to example embodiments.

FIG. 2 is a diagram illustrating a display panel electrically connected to the overcurrent detecting circuit of FIG. 1.

FIG. 3 is a diagram illustrating an example of power voltage measurement lines included in the overcurrent detecting circuit of FIG. 1.

FIG. 4 is a circuit diagram illustrating an example of a voltage measurement unit included in the overcurrent detecting circuit of FIG. 1.

FIG. 5 is a circuit diagram illustrating an example of a control unit included in the overcurrent detecting circuit of FIG. 1.

FIG. 6 is a block diagram illustrating a display device including the overcurrent detecting circuit of FIG. 1.

FIG. 7 is a block diagram illustrating an overcurrent detecting circuit according to example embodiments.

FIG. 8 is a diagram illustrating an example of input power voltage measurement lines and output power voltage measurement lines included in the overcurrent detecting circuit of FIG. 7.

FIG. 9 is a circuit diagram illustrating an example of a voltage measurement unit included in the overcurrent detecting circuit of FIG. 7.

FIG. 10 is a circuit diagram illustrating an example of a control unit included in the overcurrent detecting circuit of FIG. 7.

FIG. 11 is a block diagram illustrating a display device including the overcurrent detecting circuit of FIG. 7.

FIG. 12 is a block diagram illustrating a leakage current detecting circuit according to example embodiments.

FIG. 13 is a circuit diagram illustrating an example of a switching unit and a measurement unit included in the leakage current detecting circuit of FIG. 12.

FIG. 14 is a block diagram illustrating a display device including the leakage current detecting circuit of FIG. 12.

### DETAILED DESCRIPTION OF CERTAIN INVENTIVE EMBODIMENTS

Flat panel displays typically use relatively high currents compared to other electronic devices. Accordingly, when cracked or a power supply voltage line is abnormally shorted, burning or fire caused by overcurrent may occur.

Hereinafter, the described technology will be explained in detail with reference to the accompanying drawings. In this disclosure, the term “substantially” includes the meanings of completely, almost completely or to any significant degree under some applications and in accordance with those skilled in the art. Moreover, “formed on” can also mean “formed over.” The term “connected” can include an electrical connection.

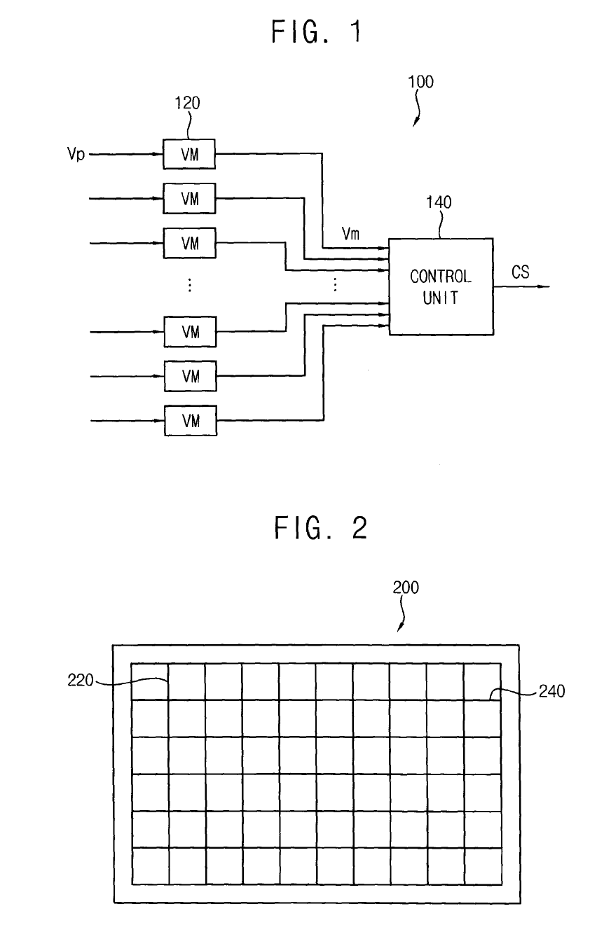

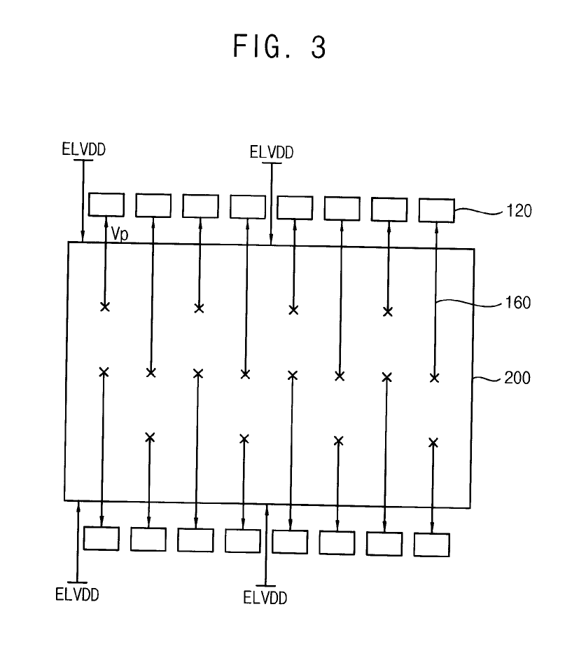

FIG. 1 is a block diagram illustrating an overcurrent detecting circuit according to example embodiments. FIG. 2 is a diagram illustrating a display panel electrically connected to the overcurrent detecting circuit of FIG. 1. FIG. 3 is a diagram illustrating an example of power voltage measurement lines included in the overcurrent detecting circuit of FIG. 1.

Referring to FIGS. 1 through 3, an overcurrent detecting circuit or overcurrent detector 100 includes a plurality of power voltage measurement lines 160, a plurality of voltage measurement units 120, and a control unit or controller 140. When a power voltage Vp supplies power to the display panel 200 through the power supply lines 220, the power voltage measurement lines 220 can be electrically connected to different points of the power supply lines 220. The voltage measurement units 120 can be respectively formed to the power voltage measurement lines 160. The voltage measurement units 120 can measure the power voltage Vp at the different points of the power supply line 220 through the power voltage measurement lines 160 and generate a plurality of measurement voltages Vm based at least in part on the measured power voltage Vp at the different points. The control unit 140 can determine whether an overcurrent occurs based at least in part on the measurement voltages Vm.

Specifically, the power voltage measurement lines 160 can be electrically connected to the different points of the power supply line 220. Referring to FIG. 2, a power signal ELVDD supplied from a power supply unit is applied to each of the pixels of the display panel 200 through the power supply line 220. A plurality of the power supply units can be electrically connected to the display panel 200 depending on a size and a resolution of the display panel 200. The power supply lines 220 can be electrically connected to a mesh line 240 to overcome a voltage drop problem occurred by an internal resistor of the power supply line 220. Further, lines (not shown) for applying a ground signal ELVSS provided from the power supply unit can be formed on the display panel.

Referring to FIG. 3, the power supply lines 220 is electrically connected to the power voltage measurement lines 160. The power voltage measurement lines 160 can measure the power voltage at the different points of the power supply line 220. In some example embodiments, the power voltage measurement lines 160 are electrically connected to a point of the power supply line 220 near to the power supply unit. In some example embodiments, the power voltage measurement lines 160 are electrically connected to a point of the power supply line 220 far from the power supply unit. An arrangement of the power voltage measurement lines 160 is not limited to FIG. 3. For example, the power voltage measurement lines 160 is additionally electrically connected to another point of the power supply line 220 on which the crack or the short defect often occurs.

Referring to FIG. 1, the voltage measurement units 120 are respectively formed to the power voltage measurement lines 160. Each of the voltage measurement units 120 can measure the power voltage Vp of the power supply line 220 through the power voltage measurement lines 160 and can generate the measurement voltage Vm based at least in part on the measured power voltage Vp. Specifically, each of the voltage measurement units 120 can include a comparator that compares the power voltage Vp to a predetermined reference voltage. Here, the reference voltage can be set based at least in part on amounts of the voltage drop of the power voltage Vp by the internal resistor of the power supply line 220, amounts of a driving current of the pixel, etc. The comparator can output the measurement voltage Vm having a first voltage level when the power voltage Vp is lower than the reference voltage. Further, the comparator can output the measurement voltage Vm having a second voltage level when the power voltage Vp exceeds the reference voltage.

The control unit 140 can determine whether the overcurrent occurs based at least in part on the measurement voltages Vm. The control unit 140 can receive the measurement voltages Vm from the voltage measurement units 120. The control unit 140 can determine that the overcurrent occurs when at least one of the measurement voltages Vm has the first voltage level. For example, the control unit 140 includes a logic circuit such as an AND gate. The control unit 140 can cut off the power voltage Vp supplied to the display panel 200 when the overcurrent occurs. For example, the control unit 140 outputs a control signal CS that cuts off an operation of a power management IC. Although the overcurrent detecting circuit 100 that includes one of the control units 140 is illustrated in FIG. 1, one or more of the control units 140 can be formed and can control the power supply to the display panel 200.

A typical overcurrent detecting circuit can determine whether an overcurrent supplied to a display panel occurs during a non-emission period of a display device. Thus, when a display device is driven without the non-emission period, for example, when the display device is driven with a digital driving method, the typical overcurrent detecting circuit cannot detect the overcurrent. However, as described above, the overcurrent detecting circuit 100 according to example embodiments can measure the power voltages Vp of the power supply lines 220 through the power voltage measurement lines 160 electrically connected to the different points of the power supply line 220 and determine whether the overcurrent occurs based at least in part on the measurement voltages Vm generated by comparing the power voltages Vp to the reference voltage, even if the display device is driven without the non-emission period, or for example, even if the display device is driven with a digital driving method. The overcurrent detecting circuit 100 according to example embodiments detects overcurrent and can protect the display device from burning.

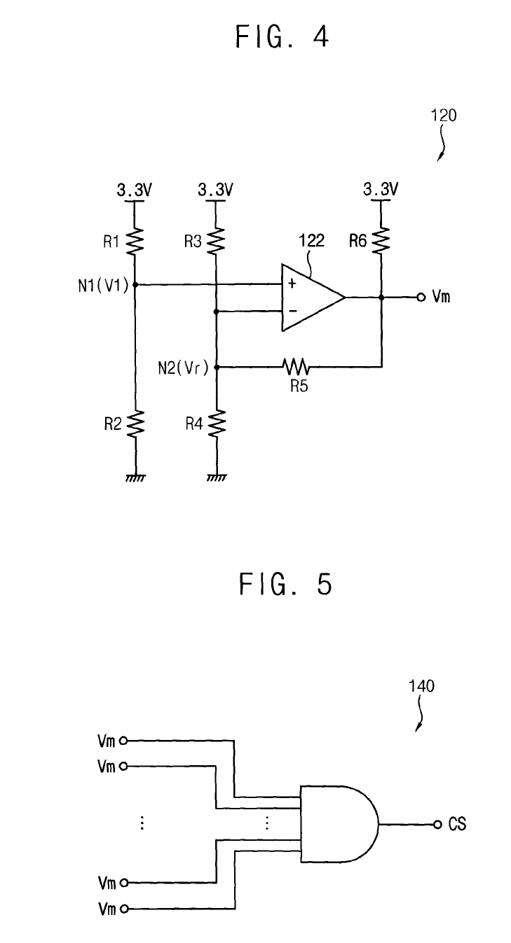

FIG. 4 is a circuit diagram illustrating an example of a voltage measurement unit included in the overcurrent detecting circuit of FIG. 1. FIG. 5 is a circuit diagram illustrating an example of a control unit included in the overcurrent detecting circuit of FIG. 1.

Referring to FIG. 4, the voltage measurement unit 120 includes a comparator 122 and a first through sixth resistors R1 through R6. The comparator 122 can compare the power voltage Vp to the reference voltage Vr and output a comparing value of the power voltage Vp to the reference voltage Vr as the measurement voltage Vm. A first voltage V1 of the first node N1 can be determined by the first resistor R1 and the second resistor R2 when the power voltage Vp is applied to the power measurement unit 120. Further, a reference voltage Vr of the second node N2 can be determined by the third to fifth resistor R3 to R5. Here, the reference voltage Vr can have a predetermined voltage value. The reference voltage Vr can be set by controlling the third resistor R3, the fourth resistor R4, and the fifth resistor R5 based at least in part on amounts of the voltage drop by the internal resistor of the power supply line 220, amounts of a driving current of the pixel, etc. The comparator 122 can compare the first voltage V1 to the reference voltage Vr. Specifically, the comparator 122 can output the measurement voltage Vm having the first voltage level in case that the first voltage V1 is lower than the reference voltage Vr. Further, the comparator 122 can output the measurement voltage Vm having the second voltage level in case that the first voltage V1 exceeds the reference voltage. For example, the first voltage V1 of the first node N1 can be dropped if the power voltage Vp drops by a crack or a short defect of the display panel 200. The comparator 122 can output the measurement voltage Vm having the first voltage level when the first voltage V1 is dropped lower than the reference voltage Vr.

Referring to FIG. 5, the control unit 140 can determine whether the overcurrent occurs based at least in part on the measurement voltages Vm. For example, the control unit 140 can include the logic circuit such as the AND gate. The control unit 140 can determine whether the overcurrent occurs based at least in part on the measurement voltages Vm and can cut off the power voltage supplied to the display panel 200 when the overcurrent occurs. Specifically, the control unit 140 determines that the overcurrent occurs when at least one of the measurement voltages has the first voltage level. The control unit 140 can cut off the power voltage supplied to the display panel 200. For example, the control unit 140 can output a control signal CS that cut off the operation of the power management IC.

As described, the overcurrent detecting circuit 100 according to example embodiments can include the voltage measurement unit 120 and the control unit 140. The voltage measurement unit 120 can generate the measurement voltage Vm by comparing the power voltage Vp of the power supply line formed on the display panel 200 to the reference voltage Vr. The voltage measurement unit 120 can output the measurement voltage Vm having the first voltage level when the power voltage Vp is lower than the reference voltage Vr. The control unit 140 can determine whether the overcurrent occurs based at least in part on the measurement voltage Vm output from the voltage measurement units 120. The control unit 140 can determine that the overcurrent occurs when at least one of the measurement voltages Vm has the first voltage level and prevent a defect of the display panel by cutting off the power voltage supplied to the display panel 200.

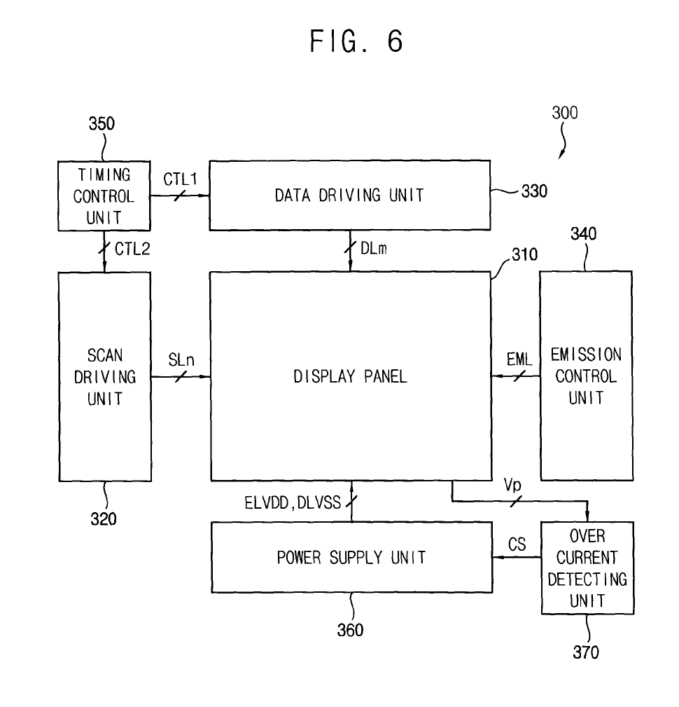

FIG. 6 is a block diagram illustrating a display device including the overcurrent detecting circuit of FIG. 1.

Referring to FIG. 6, the display device 300 includes a display panel 310, a scan driving unit or scan driver 320, a data driving unit or data driver 330, an emission control unit or emission controller 340, a timing control unit or timing controller 350, a power supply unit 360, and an overcurrent detecting unit or overcurrent detector 370. Here, the overcurrent detecting unit 370 can correspond to the overcurrent detecting circuit 100 of FIG. 1.

The display panel 310 can include a pixels. Here, each pixel can include an organic light-emitting diode (OLED). In some example embodiment, each pixel includes a pixel circuit, a driving transistor, and an OLED. In this case, the pixel circuit operates to provide a data signal, where the data signal is provided via data-lines DLm, to the driving transistor based at least in part on a scan signal, where the scan signal is provided via scan-lines SLn. The driving transistor can control a current flowing through the OLED based at least in part on the data signal, and the OLED can emit light based at least in part on the current.

The scan driving unit 320 can provide the scan signal to the pixels via the scan-lines SLn. The data driving unit 330 can provide the data signal to the pixels via the data-lines DLm. The timing control unit 350 can control the scan driving unit 320, the data driving unit 330 and the emission control unit 340 by generating a control signals CTL1 and CTL2. The power supply unit 360 can provide power signals ELVDD and ELVSS to the display panel 310.

The overcurrent detecting unit 370 can prevent defects of the display panel 310 by cutting off a power signal of the power supply unit 360 when a crack occurs in the display panel 310 or the power supply line is abnormally shorted. Specifically, the power measurement lines can be electrically connected to different points of a power supply line of the display panel. The voltage measurement unit can be electrically connected to each power voltage measurement line. The voltage measurement unit can output a measurement voltage by comparing a power voltage supplied through the power voltage measurement line to a reference voltage. When a crack of the display panel or a short of the power supply line occurs, the power voltage can be dropped below the reference voltage. Thus, the voltage measurement unit can output a measurement voltage having a first voltage level. The control unit can determine whether the overcurrent occurs based at least in part on the measurement voltages. The control unit can determine that the overcurrent occurs on the display panel 310 when at least one of the measurement voltages has the first voltage level and can output a control signal CS that cut off the power voltage supplied to the display panel 310. As described, the display device 300 according to example embodiments includes the overcurrent detecting unit 370 that measures the power voltages of the different points of the power supply line and determine whether the overcurrent occurs based at least in part on the measurement voltage generated by comparing the power voltage to the reference voltage. Thus, a defect of the display device 300 can be prevented by detecting the overcurrent even if the display device is driven with the digital driving method.

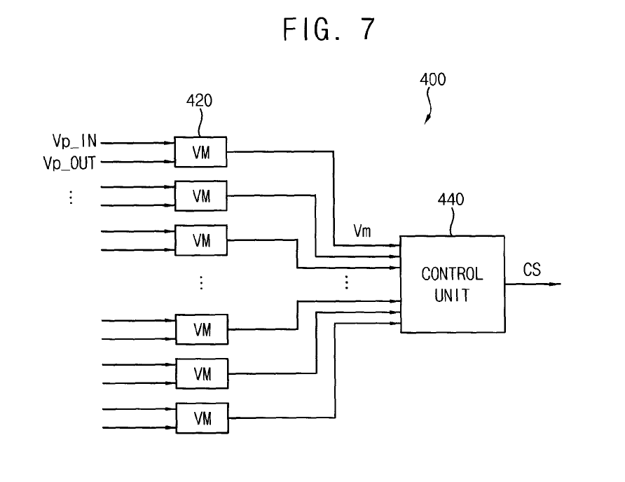

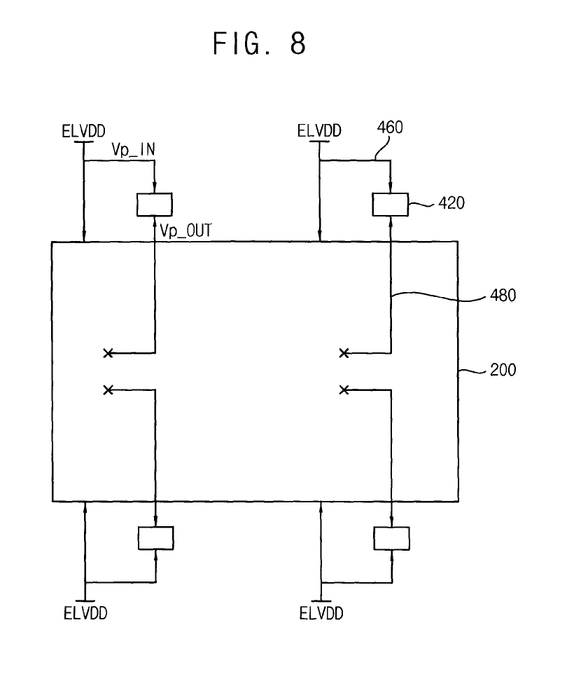

FIG. 7 is a block diagram illustrating an overcurrent detecting circuit according to example embodiments. FIG. 8 is a diagram illustrating an example of input power voltage measurement lines and output power voltage measurement lines included in the overcurrent detecting circuit of FIG. 7.

Referring to FIGS. 7 and 8, an overcurrent detecting circuit 100 includes a plurality of input power voltage measurement lines 460, a plurality of output power voltage measurement lines 480, and a control unit or controller 440. When a power voltage supplies power to the display panel through a plurality of power supply lines, the input power voltage measurement lines 460 and a plurality of output power voltage measurement lines 480 can be electrically connected to the power supply lines. The input power voltage measurement lines 460 can be formed to measure a first power voltage Vp_IN of the power supply line before a voltage drop of the power voltage occurs. The output power voltage measurement lines 480 can be formed to measure a second power voltage Vp_OUT of the power supply line after the voltage drop of the power voltage occurs. The voltage measurement units 420 can generate a plurality of measurement voltages Vm by measuring the first power voltage Vp_IN measured through the input power voltage measurement lines 460 and the second power voltage Vp_OUT measured through the output power voltage measurement lines 480. The control unit 440 can determine whether the overcurrent occurs based at least in part on the measurement voltages Vm.

Specifically, the input power voltage measurement lines 460 can be formed on a display panel to measure a power voltage before the voltage drop of the power voltage occurs, that is, the first power voltage Vp_IN. Here, the display panel can correspond to the display panel 200 of FIG. 2. The power signal ELVDD supplied from the power supply unit can be applied to each of the pixels of the display panel 200 through the power supply line 220. At least one of the power supply unit can be electrically connected to the display panel 200 based at least in part on a size and a resolution of the display panel 200. As a distance from the power supply increases, the voltage drop of the power supply lines 220 can increase by an internal resistor of the power supply lines 220. Referring to FIG. 8, the first power voltage Vp_IN (that is, the power voltage before the voltage drop occurs) is measured through the input power voltage measurement lines 460. For example, the input power voltage measurement lines 460 can be electrically connected to the power supply line 220 at a point near the power supply unit. The second power voltage Vp_OUT (that is, the power voltage after the voltage drop occurs) can be measured through the output power voltage measurement lines 480. For example, the output power voltage measurement lines 480 are electrically connected to the power supply line 220 at a point apart from the power supply unit. As described, the input power voltage measurement line 460 can be electrically connected to the power supply line near the power supply unit to measure the first power voltage Vp_IN (that is, the power voltage before the voltage drop occurs) and the output power voltage measurement line 480 can be electrically connected to the power supply line far from the power supply unit to measure the second power voltage Vp_OUT (that is, the power voltage after the voltage drop occurs).

The voltage measurement units 420 can be electrically connected to the input power voltage measurement line 460 and the output power voltage measurement line 480 that are electrically connected to the same power supply line 220. Each of the voltage measurement units 420 can measure the first power voltage Vp_IN and the second power voltage Vp_OUT and can generate a measurement voltage Vm based at least in part on the first and second power voltages Vp_IN and Vp_OUT. Specifically, each of the voltage measurement units 420 can include a calculator and a comparator. The calculator can calculate a difference between the first and second power voltages Vp_IN and Vp_OUT. The comparator can compare an output voltage of the calculator to a reference voltage. Here, the reference voltage can be set based at least in part on amounts of the voltage drop by the internal resistor of the power supply line 220, amounts of a driving current of the pixel, etc. The comparator can output the measurement voltage Vm having a first voltage level when the voltage output from the calculator is lower than the reference voltage. Further, the comparator can output the measurement voltage Vm having a second voltage level when the voltage output from the calculator exceeds the reference voltage.

The control unit 440 can determine whether the overcurrent occurs based at least in part on the measurement voltages Vm. The control unit 440 can receive the measurement voltages Vm from the voltage measurement units 420. The control unit 440 can determine that the overcurrent occurs when at least one of the measurement voltages Vm has the first voltage level. For example, the control unit 440 includes a logic circuit such as an AND gate. The control unit 440 can cut off the power voltage Vp supplied to the display panel 200 when the overcurrent occurs. For example, the control unit 440 outputs a control signal CS that cuts off an operation of a power management IC. Although the overcurrent detecting circuit 400 that includes one control unit 440 is illustrated in FIG. 7, one or more control units 440 can be formed and can control the power supply to the display panel 200.

A typical overcurrent detecting circuit can determine whether an overcurrent supplied to a display panel occurs during a non-emission period of a display device. Thus, in example embodiments, when a display device is driven without the non-emission period, for example when the display device is driven with a digital driving method, the typical overcurrent detecting circuit does not detect the overcurrent. However, as described above, the overcurrent detecting circuit 400 of the display device according to example embodiments measures the first power voltage Vp_IN (that is, the power voltage before the voltage drop occurs) and the second power voltage Vp_OUT (that is, the power voltage after the voltage drop occurs) and determine whether the overcurrent occurs based at least in part on the measurement voltages Vm generated by the difference between the first power voltage Vp_IN and the second power voltage Vp_OUT, even if the display device is driven without the non-emission period or with a digital driving method. The overcurrent detecting circuit 400 according to example embodiments can detect overcurrent and can protect the display device from burning.

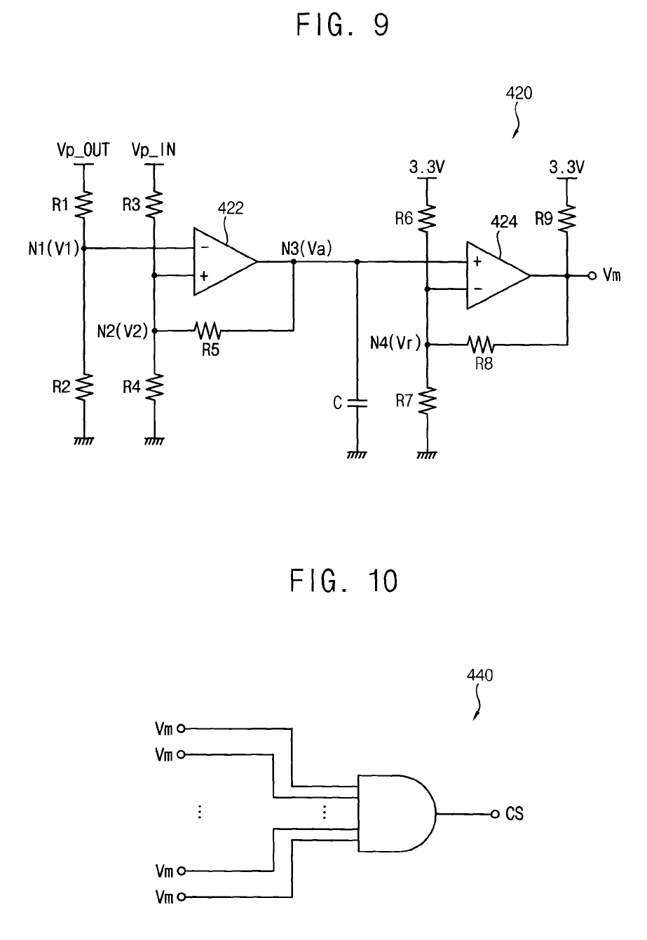

FIG. 9 is a circuit diagram illustrating an example of a voltage measurement unit included in the overcurrent detecting circuit of FIG. 7. FIG. 10 is a circuit diagram illustrating an example of a control unit included in the overcurrent detecting circuit of FIG. 7.

Referring to FIG. 9, the voltage measurement unit 420 can include the calculator 422, the comparator, and a first through ninth resistors R1 through R9. The calculator 422 can calculate the difference between the first and second power voltages Vp_IN and Vp_OUT. A first voltage V1 of a first node N1 can be determined by the first resistor R1 and the second resistor R2 when the first power voltage Vp_IN is applied to the voltage measurement unit 420. Further, a second voltage V2 of a second node N2 is determined by the third to fifth resistors R3 to R5. The output voltage of the calculator 422, that is, a calculation voltage Va of a third node N3 can be changed by the difference between the first voltage V1 of the first node N1 and the second voltage V2 of the second node N2. Here, the calculation voltage Va of the third node N3 can be applied to the comparator 424. Specifically, when the difference between the first voltage V1 of the first node N1 and the second voltage V2 of the second node N2 increases, the calculation voltage Va can decrease. When the difference between the first voltage V1 of the first node N1 and the second voltage V2 of the second node N2 decreases, the calculation voltage Va can increase. For example, when the crack occurs in the display panel or the power supply line 220 is abnormally shorted, the first voltage V1 of the first node N1 decreases and the calculation voltage Va decreases. The comparator 424 can compare the calculation voltage Va to a reference voltage Vr of a fourth node N4. The reference voltage Vr of the fourth node N4 can be determined by the sixth to ninth resistors R6 to R9. The reference voltage Vr of the fourth node N4 can be set by controlling the sixth to ninth resistors R6 to R9 based at least in part on amounts of the voltage drop by the internal resistor of the power supply line 220, amounts of a driving current of the pixel, etc. The comparator 424 can compare the calculation voltage Va to the reference voltage Vr. Specifically, the comparator 424 can output a measurement voltage Vm having a first voltage level when the calculation voltage Va is lower than the reference voltage Vr. Further, the comparator 424 can output the measurement voltage Vm having a second voltage level when the calculation voltage Va exceeds the reference voltage Vr. For example, when the crack occurs in the display panel or the power supply line 220 is abnormally shorted, the first voltage V1 of the first node N1 is dropped and the calculation voltage Va decreases. The comparator 424 can output the measurement voltage Vm when the calculation voltage Va is lower than the reference voltage.

Referring to FIG. 10, the control unit 440 determines whether the overcurrent occurs based at least in part on the measurement voltages Vm. For example, the control unit 440 includes the logic circuit such as the AND gate. The control unit 440 can determine whether the overcurrent occurs based at least in part on the measurement voltages Vm and can cut off the power voltage supplied to the display panel 200 when the overcurrent occurs. Specifically, the control unit 440 can determine that the overcurrent occurs when at least one of the measurement voltages has the first voltage level. The control unit 440 can cut off the power voltage supplied to the display panel 200. For example, the control unit 440 outputs a control signal CS that cut off the operation of the power management IC.

As described, the overcurrent detecting circuit 400 according to example embodiments includes the voltage measurement unit 420 and the control unit 440. The voltage measurement unit 420 can generate the measurement voltage Vm based at least in part on the first power voltage Vp_IN (that is, the voltage measured before voltage drop occurs) and the second power voltage Vp_OUT (that is, the voltage measured after voltage drop occurs). The voltage measurement unit 420 includes the calculator 422 and the comparator 424. The calculator 422 can calculate the difference between the first power voltage Vp_IN and the second power voltage Vp_OUT and output the difference as the calculation voltage Va. The comparator 424 can compare the calculation voltage Va to the reference voltage Vr. For example, when the crack occurs in the display panel 200 or the power supply line is abnormally shorted, the second power voltage Vp_OUT decreases and the calculation voltage Va decreases. The comparator 424 can output the measurement voltage Vm having the first voltage level when the calculation voltage Va decreases lower than the reference voltage Vr. The control unit 440 can determine whether the overcurrent occurs based at least in part on the measurement voltage Vm output from the voltage measurement units 420. The control unit 440 can determine that the overcurrent occurs when at least one of the measurement voltages Vm has the first voltage level and prevent a defect of the display panel by cutting off the power voltage supplied to the display panel 200.

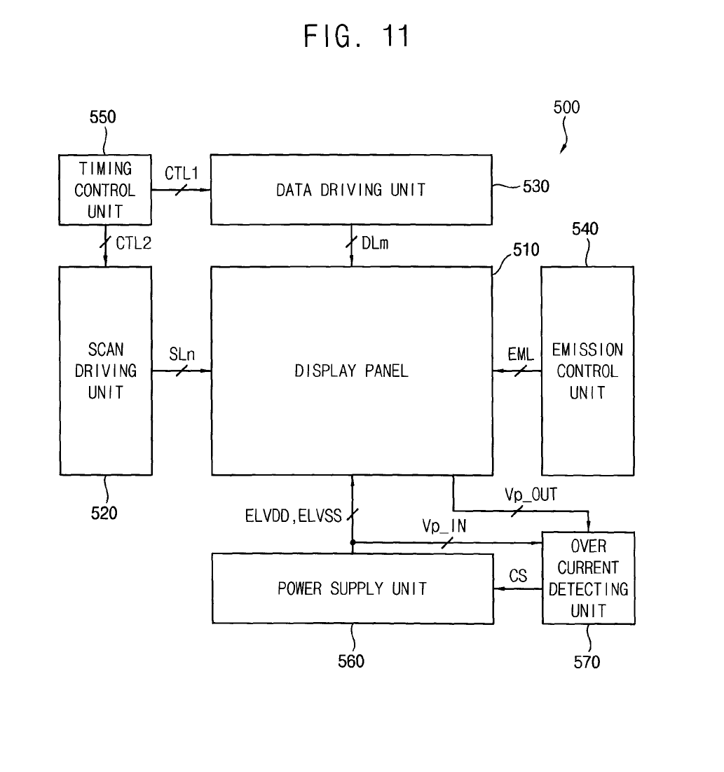

FIG. 11 is a block diagram illustrating a display device including the overcurrent detecting circuit of FIG. 7.

Referring to FIG. 11, the display device 500 includes a display panel 510, a scan driving unit 520, a data driving unit 530, an emission control unit 540, a timing control unit 550, a power supply unit 560, and an overcurrent detecting unit 570. Here, the overcurrent detecting unit 570 can correspond to the overcurrent detecting circuit 400 of FIG. 7.

The display panel 510 includes a plurality of pixels. Here, each pixel can include an OLED. In some example embodiment, each pixel can include a pixel circuit, a driving transistor, and an OLED. In this case, the pixel circuit can operate to provide a data signal, where the data signal is provided via data-lines DLm, to the driving transistor based at least in part on a scan signal, where the scan signal is provided via scan-lines SLn. The driving transistor can control a current flowing through the OLED based at least in part on the data signal, and the OLED can emit light based at least in part on the current.

The scan driving unit 520 can provide the scan signal to the pixels via the scan-lines SLn. The data driving unit 530 can provide the data signal to the pixels via the data-lines DLm. The timing control unit 550 can control the scan driving unit 520, the data driving unit 530 and the emission control unit 540 by generating a plurality of control signals CTL1 and CTL2. The power supply unit 560 can provide power signals ELVDD and ELVSS to the display panel 510.

The overcurrent detecting unit 570 can prevent defects of the display panel 510 by cutting off a power signal of the power supply unit 560 when a crack occurs in the display panel 510 or the power supply line is abnormally shorted. Specifically, a plurality of input power voltage measurement lines and a plurality of output power voltage measurement lines can be electrically connected to a power supply line of the display panel. The input power voltage measurement lines can be formed to measure the first power voltage Vp_IN (that is, the voltage measured before the voltage drop occurs) and the output power voltage measurement lines can be formed to measure the second power voltage Vp_OUT (that is, the voltage measured after the voltage drop occurs). The voltage measurement units can measure the first power voltage Vp_IN through the input power voltage measurement line and the second power voltage Vp_OUT through the output power voltage measurement line. The voltage measurement units can generate the measurement voltage based at least in part on the and second power voltages Vp_IN and Vp_OUT. The voltage measurement unit can generate the calculation voltage by calculating the difference between the first and second power voltages Vp_IN and Vp_OUT and generate the measurement voltage by comparing the calculation voltage to the reference voltage. When a crack of the display panel or a short of the power supply line occurs, the voltage measurement unit can output the measurement voltage having the first voltage level. The control unit can determine whether the overcurrent occurs based at least in part on the measurement voltages. The control unit can determine that the overcurrent occurs on the display panel 510 when at least one of the measurement voltages has the first voltage level and can output a control signal CS that cuts off the power voltage supplied to the display panel 510. As described, the display device 500 according to example embodiments includes the overcurrent detecting unit 570 that measures the first power voltage Vp_IN (that is, the voltage measured before the voltage drop occurs) and the second power voltage Vp_OUT (that is, the voltage measured after the voltage drop occurs) and determine whether the overcurrent occurs based at least in part on the measurement voltage generated by the first power voltage Vp_IN and the second power voltage Vp_OUT. Thus, the defect of the display device 500 can be prevented by detecting the overcurrent even if the display device 500 is driven with the digital driving method.

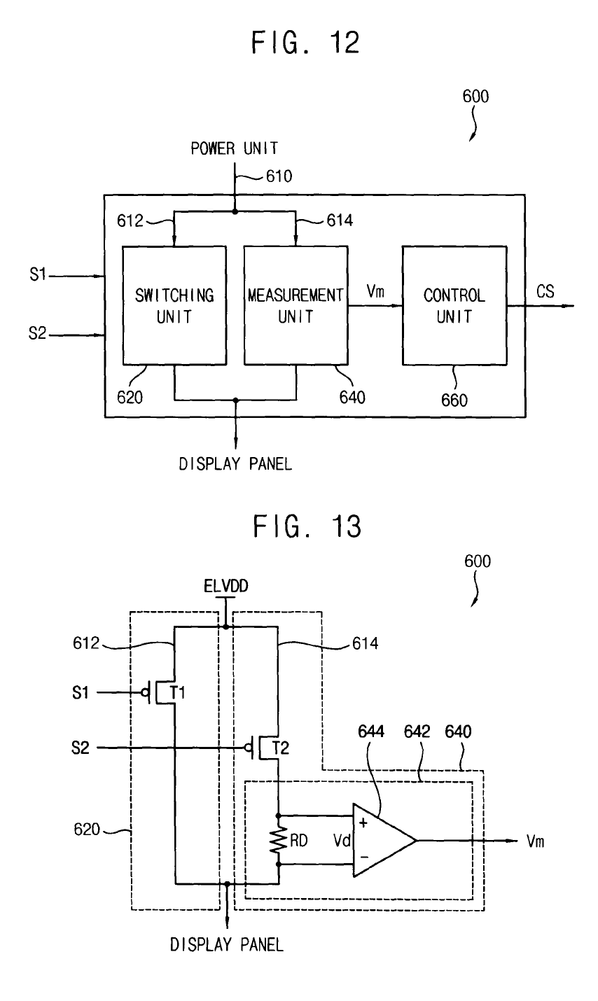

FIG. 12 is a block diagram illustrating a leakage current detecting circuit according to example embodiments. FIG. 13 is a circuit diagram illustrating an example of a switching unit and a measurement unit included in the leakage current detecting circuit of FIG. 12.

Referring to FIGS. 12 and 13, a leakage current detecting circuit 600 is formed between a power supply unit and the display panel when a power voltage supplies to the display panel having the pixels through a power supply line 610. The leakage current detecting circuit 600 can be electrically connected to the power supply line 610. The leakage current detecting circuit 600 can include a switching unit 612, a measurement unit 640, and a control unit 660. The power supply line 610 can include a first power supply line 612 electrically connected to the switching unit 620 and a second power supply line 614 electrically connected to the measurement unit 640. The switching unit 620 can transfer the power voltage provided through the first power supply line 612 to the display panel based at least in part on a first signal S1 from an external device. The measurement unit 640 can transfer the power voltage provided through the second power supply line 614 to the display panel based at least in part on a second signal S2 from the external device and generate a measurement voltage Vm corresponding to a current that flows through the second power supply line 614. The control unit 660 can determine whether the leakage current occurs based at least in part on the measurement voltage Vm.

Referring to FIG. 13, the switching unit 620 includes a first transistor T1 that is turned on based at least in part on the first signal S1. When the first signal S1 is applied to the first switching transistor T1, the first switching transistor T1 can be turned on and the power voltage can be applied to the display panel through the first power supply line 612. In some example embodiments, the first switching transistor T1 can be turned off when a black image is displayed on the display panel.

The measurement unit 640 can include a second switching transistor T2 that is turned on based at least in part on the second signal S2 and a current sensing unit 642. When the second signal S2 is applied to the second switching transistor T2, the second transistor T2 can be turned on and the power voltage can be applied to the display panel through the second power supply line 614. The current sensing unit 642 can detect the current that flows through the second power supply line 614. In some example embodiments, the second switching transistor T2 can be turned on in case that a black image is displayed on the display panel. When the second switching transistor T2 of the measurement unit 640 is turned on, the power voltage can be provided to the display panel through the second power supply line 614 and the current sensing unit 642 can detect the current that flows through the second power supply line 614. For example, when the display device is turned on or turned off, the black image is displayed on the display panel and the second signal S2 is applied to the second switching transistor T2. The current sensing unit 642 can include a sense resistor RD and an amplifier 644 as a current sensor that senses the current that flows through the second power supply line 614. In some embodiments, the sense resistor RD has a low resistance such that a voltage or a current supplied to the pixel through the second power supply line 614 is not substantially affected by the sense resistor RD. The amplifier 644 can generate the measurement voltage Vm by amplifying a sense voltage Vd generated by the sense resistor RD. When the black image is displayed on the display panel, the driving current that provided to the pixel can be zero. Thus, the current that flows through the second power supply line 614 can be zero. Therefore, the control unit 660 can determine that the leakage current occurs when the measurement voltage Vm detected by the current sensing unit 642 is not zero.

The control unit 660 can determine that the leakage current occurs when the measurement voltage Vm is higher than a predetermined reference voltage. For example, the reference voltage is at or near zero and a current value that flows through the power supply line 610 is at or near zero when the black image is displayed on. The control unit 660 can output a control signal CS that cuts off the power voltage supplied to the display panel when the leakage current occurs.

As described, the leakage current detecting circuit 600 can be formed between the power supply unit and the display panel. The leakage current detecting circuit 600 can detect the leakage current based at least in part on the second signal S2 that is applied when the display panel is turned on or turned off. Specifically, the leakage current detecting circuit 600 can include the switching unit 612 and the measurement unit 640. The switching unit 612 can include a first switching transistor T1 that is turned on based at least in part on the first signal S1. The power voltage can be transferred to the display panel through the first power supply line 612 when the first switching transistor T1 is turned on. The measurement unit 640 can include the second switching transistor T2 that is turned on based at least in part on the second signal S2 and the current sensing unit 642. The power voltage can be transferred to the display panel through the second power supply line 614 when the second switching transistor T2 is turned on. The current sensing unit 642 can sense the current that flows through the second power supply line 614. Here, the second signal S2 can be applied when the black image is displayed on the display panel. Thus, the current that flows through the second power supply line 614 can be at or near zero. The current sensing unit 642 can convert the current that flows through the second power supply line 614 to the measurement voltage Vm and transfer the measurement voltage Vm to the control unit 660. The control unit 660 can determine that the leakage current occurs when the measurement voltage Vm is higher than a reference voltage and can output the control signal CS that cuts off the power voltage supplied to the display panel. As described above, the leakage current detecting circuit 600 can detect the leakage current that flows through the power supply line 610.

A typical leakage current detecting circuit can determine whether a leakage current occurs during a non-emission period of a display device. Thus, when a display device is driven without the non-emission period, for example when the display device is driven with a digital driving method, the typical leakage current detecting unit does not detect the leakage current. However, as described above, the leakage current detecting circuit 600 according to example embodiments displays the black image on the display panel when the display device is turned on or turned off and determines whether the leakage current occurs based at least in part on the measurement voltage Vm corresponding to the current that flows through the power supply line 610, even if the display device is driven without the non-emission period, or for example even if the display device is driven with a digital driving method. The leakage current detecting circuit 600 according to example embodiments can detect leakage current and can protect the display device from burning.

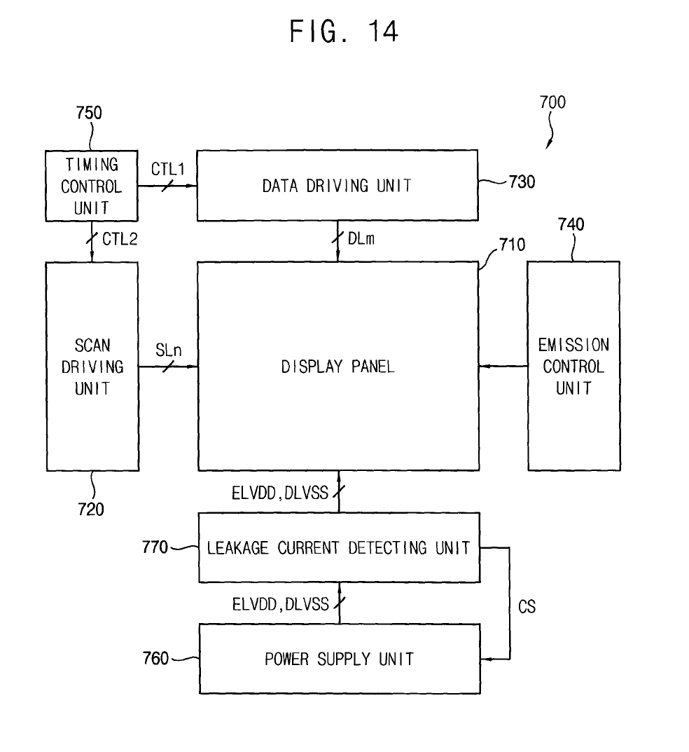

FIG. 14 is a block diagram illustrating a display device including the leakage current detecting circuit 600 of FIG. 12.

Referring to FIG. 14, the display device 700 includes a display panel 710, a scan driving unit 720, a data driving unit 730, an emission control unit 740, a timing control unit 750, a power supply unit 760, and a leakage current detecting unit 770. Here, the leakage current detecting unit 770 can correspond to the leakage current detecting circuit 600 of FIG. 12.

Here, each pixel can include an OLED. In some example embodiment, each pixel includes a pixel circuit, a driving transistor, and an OLED. In this case, the pixel circuit provides a data signal via data-lines DLm to the driving transistor based at least in part on a scan signal provided via scan-lines SLn. The driving transistor can control a current that flows through the OLED based at least in part on the data signal, and the OLED can emit light based at least in part on the current.

The scan driving unit 720 can provide the scan signal to the pixels via the scan-lines SLn. The data driving unit 730 can provide the data signal to the pixels via the data-lines DLm. The timing control unit 750 can control the scan driving unit 520, the data driving unit 530 and the emission control unit 740 by generating the control signals CTL1 and CTL2. The power supply unit 760 can provide power signals ELVDD and ELVSS to the display panel 710.

The leakage current detecting unit 770 can be formed between the power supply unit 760 and the display panel 710. The leakage current detecting unit 770 can include a switching unit, a measurement unit, and a control unit. The power supply line can include a first power supply line electrically connected to the switching unit and a second power supply line electrically connected to the measurement unit. The switching unit can include a first switching transistor that is turned on based at least in part on the first signal. The switching unit can transfer the power voltage provided through the first power supply line to the display panel 710 when the first switching transistor is turned on. The measurement unit can include a second switching transistor that is turned on based at least in part on a second signal and a current sensing unit. The measurement unit can transfer the power voltage provided through the second power supply line to the display panel 710 when the second switching transistor is turned on. The current sensing unit can sense a current that flows through the second power supply line. The current sensing unit can convert the sensed current to the measurement voltage. The first signal is applied to the switching unit when the black image is not displayed on the display panel 710 and the second signal is applied to the measurement unit when the black image is displayed on the display panel 710. Here, the second signal can be applied when the display device 700 is turned on or turned off. For example, the current that flows through the second power supply line is at or near zero when the black image is displayed on the display panel 710. The control unit can determine that the leakage current occurs when the measurement voltage is higher than a predetermined reference voltage and output a control signal CS that cuts off the power voltage supplied to the display panel 710. The control signal CS can be provided to the power supply unit 760 to cut off the power voltage supplied to the display panel 710.

As described, the display device 700 according to example embodiments can include the leakage current detecting unit 770 between the power supply unit 760 and the display panel 710. The leakage current detecting unit 770 can detect the leakage current based at least in part on the second signal S2 that is applied when the display panel is turned on or turned off. Specifically the leakage current detecting unit 770 can include the switching unit and the measurement unit. The switching unit can transfer the power voltage to the display panel 710 through the first power voltage supply line during the first signal is applied. The measurement unit can transfer the power voltage to the display panel 710 through the second power voltage supply line and can sense the current that flows through the second power voltage supply line during the second signal is applied. Further, the measurement unit can convert the current that flows through the second power voltage supply line to the measurement voltage. The control unit can determine that the leakage current occurs when the measurement voltage is higher than a predetermined reference voltage and output a control signal CS that cuts off the power voltage supplied to the display panel 710. As described, the leakage current detecting unit 770 according to example embodiments can detect the current that flows through the power supply line and determine whether the leakage current occurs. Thus, the defect of the display device 700 can be prevented by detecting the leakage current even if the display device 700 is driven with the digital driving method.

The described technology can be applied to a display device having a display panel. For example, the described technology can be applied to a computer monitor, a laptop, a digital camera, a cellular phone, a smartphone, a smart pad, a television, a personal digital assistant (PDA), a portable multimedia player (PMP), a MP3 player, a navigation system, a game console, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the inventive technology. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. An overcurrent detecting circuit of a display device supplying a power voltage to a display panel through a plurality of power supply lines, the overcurrent detecting circuit comprising:
a plurality of power voltage measurement lines electrically connected to different points of the power supply lines;
a plurality of voltage measurement units respectively electrically connected to the power voltage measurement lines and configured to i) measure the power voltage at the different points through the power voltage measurement lines and ii) generate a plurality of measurement voltages based at least in part on the measured power voltages; and
a controller configured to detect presence of an overcurrent based at least in part on the measurement voltages.

2. The overcurrent detecting circuit of claim 1, wherein each of the voltage measurement units includes a comparator configured to compare the power voltage to a predetermined reference voltage.

3. The overcurrent detecting circuit of claim 2, wherein the comparator is further configured to output the measurement voltages having a first voltage level when the power voltage is lower than the predetermined reference voltage.

4. The overcurrent detecting circuit of claim 3, wherein the controller is further configured to detect the presence of the overcurrent when at least one of the measurement voltages has the first voltage level.

5. The overcurrent detecting circuit of claim 1, wherein the controller is further configured to cut off the power voltage supplied to the display panel when the presence of the overcurrent is detected.

6. The overcurrent detecting circuit of claim 1, wherein the controller comprises an AND gate having the measurement voltages as the input and a control signal as the output, and wherein the control signal indicates the presence of the overcurrent.

7. An overcurrent detecting circuit of a display device supplying a power voltage to a display panel through a plurality of power supply lines, the overcurrent detecting circuit comprising:
a plurality of input power voltage measurement lines formed to measure the power voltage before a voltage drop of the power voltage occurs;
a plurality of output power voltage measurement lines formed to measure the power voltage after the voltage drop of the power voltage occurs;
a plurality of voltage measurement units configured to i) measure the power voltages before and after the voltage drop occurs respectively through the input and output power voltage measurement lines and ii) generate a plurality of measurement voltages based at least in part on the measured power voltages; and
a controller configured to detect presence of an overcurrent based at least in part on the measurement voltages.

8. The overcurrent detecting circuit of claim 7, wherein each voltage measurement unit includes:
a calculator configured to output a calculation voltage that is the difference between the power voltages; and
a comparator configured to compare the calculation voltage to a predetermined reference voltage.

9. The overcurrent detecting circuit of claim 8, wherein the comparator is further configured to output the measurement voltage having a first voltage level when the power voltage is lower than the predetermined reference voltage.

10. The overcurrent detecting circuit of claim 9, wherein the controller is further configured to detect the presence of the overcurrent when at least one of the measurement voltages has the first voltage level.

11. The overcurrent detecting circuit of claim 7, wherein the controller is further configured to cut off the power voltage supplied to the display panel when the presence of the overcurrent is detected.

12. The overcurrent detecting circuit of claim 7, wherein the controller comprises an AND gate having the measurement voltages as the input and a control signal as the output, and wherein the control signal indicates the presence of the overcurrent.

13. A leakage current detecting circuit of a display device supplying a power voltage from a power supply unit to a display panel through a plurality of power supply lines, the leakage current detecting circuit comprising:
a switching unit formed between the power supply unit and the display panel and configured to provide the power voltage to the display panel based at least in part on a first signal provided from an external device;
a measurement unit formed between the power supply unit and the display panel and configured to i) transmit the power voltage to the display panel based at least in part on a second signal provided from the external device and ii) generate a measurement voltage corresponding to a current configured to flow through the power supply lines; and
a controller configured to detect presence of a leakage current based at least in part on the measurement voltage.

14. The leakage current detecting circuit of claim 13, wherein the switching unit includes a first switching transistor configured to be turned on based at least in part on the first signal.

15. The leakage current detecting circuit of claim 14, wherein the first switching transistor is configured to be turned off when a black image is displayed on the display panel.

16. The leakage current detecting circuit of claim 13, wherein the measurement unit includes:
a second switching transistor configured to be turned on based at least in part on the second signal; and
a current sensor electrically connected to the second transistor and configured to generate the measurement voltage corresponding to the current configured to flow through the power supply lines.

17. The leakage current detecting circuit of claim 16, wherein the second switching transistor is configured to be turned on when a black image is displayed on the display panel.

18. The leakage current detecting circuit of claim 13, wherein the controller is further configured to determine the presence of the leakage current when the measurement voltage is higher than a predetermined reference voltage.

19. The leakage current detecting circuit of claim 13, wherein the controller is further configured to cut off the power voltage supplied to the display panel when the presence of the leakage current is detected.

20. The leakage current detecting circuit of claim 13, wherein the controller is further configured to transmit a control signal indicating the presence of the leakage current to the power supply unit.
